(19) United States
(12) Patent Application Publication
(10) Pub. No.: US 2026/0026396 A1
(43) Pub. Date: Jan. 22, 2026

(54) OPTICAL COMPONENT, TRANSPARENT SEALING MEMBER, SUBSTRATE, AND METHOD FOR MANUFACTURING OPTICAL COMPONENT

(71) Applicant: NGK INSULATORS, LTD., Nagoya-shi (JP)

(72) Inventors: Yoshio KIKUCHI, Nagoya-shi (JP); Keijiro OKUSA, Kasugai-shi (JP); Shohei KAWAGUCHI, Komaki-shi (JP)

(21) Appl. No.: 19/341,050

(22) Filed: Sep. 26, 2025

Related U.S. Application Data
(63) Continuation of application No. PCT/JP2024/012477, filed on Mar. 27, 2024.

(30) Foreign Application Priority Data
Mar. 28, 2023 (WO) PCT/JP2023/012494

(51) Int. Cl. H01L 23/10; H10F 77/40; H10H 20/855

(52) U.S. Cl. CPC H01L 23/10; H10F 77/407; H10H 20/855

(57) ABSTRACT

An optical component including: a substrate on which an optical element is mounted; a transparent sealing member disposed above the substrate and configured to seal the optical element; and a bonded portion in which a plurality of metal films are laminated, and which is configured to bond the transparent sealing member and the substrate. The bonded portion includes: one or more stress relaxation layers constituted by one or more metal films having a Young's modulus of less than or equal to 150 GPa, the one or more stress relaxation layers having a total thickness of greater than or equal to 1.2 μm; and a diffusion prevention layer disposed on each of both sides in a thickness direction of each of the one or more stress relaxation layers, and configured to prevent diffusion of metal constituting the stress relaxation layer.

### CROSS-REFERENCE TO RELATED APPLICATIONS

This application is a Continuation of International Application No. PCT/JP2024/012477 filed on Mar. 27, 2024, which is based upon and claims the benefit of priority from International Application No. PCT/JP2023/012494 filed on Mar. 28, 2023, the contents all of which are incorporated herein by reference.

### TECHNICAL FIELD

The present invention relates to an optical component, a transparent sealing member, a substrate, and a method for manufacturing an optical component.

### BACKGROUND ART

An optical component such as a light emitting device and an optical sensor or the like has a structure in which a transparent sealing member is bonded onto a substrate on which an optical element is mounted, and the optical element is sealed with the transparent sealing member. The optical element is a light emitting element (for example, an LED or the like) or a light receiving element (for example, a photodiode). The transparent sealing member is made of glass, and is bonded onto the substrate using a low melting point alloy such as solder or the like.

JP 2021-118199 A discloses a technique of providing a metallized layer on quartz glass and a mounting substrate, in order to bond, with solder, a transparent sealing member made of quartz glass to the substrate.

JP 2019-046826 A discloses a technique of providing an Au (gold) film having a thickness of 0.3 μm to 10 μm as a stress relaxation layer in order to avoid a situation in which, at a bonded portion between a transparent sealing member made of quartz glass and a substrate, the transparent sealing member undergoes cracking due to thermal expansion.

### SUMMARY OF THE INVENTION

There are cases in which the optical component may be exposed to a high temperature due to heat that is generated by the light emitting element during usage thereof. Further, in a reflow process for the purpose of mounting the optical component, the optical component may be exposed to a high temperature, for example, on the order of 200° C. to 400° C. For this reason, a concern arises in that, at the bonded portion between the transparent sealing member and the substrate, a thermal stress may occur due to a difference in the coefficient of thermal expansion between both members, and the fragile transparent sealing member may undergo cracking or peeling off, and the sealing of the optical element may become broken.

With the metallized layer disclosed in JP 2021-118199 A, there is a possibility that a sufficient stress relaxation effect cannot be obtained.

Although the stress relaxation layer in JP 2019-046826 A is made of Au, due to interdiffusion with the adjacent low melting point alloy (the solder) in which Sn (tin) is contained, the stress relaxation layer may deteriorate, and a possibility exists in that a sufficient stress relaxation effect cannot be obtained.

The present invention has the object of solving the aforementioned problem.

Aspects of the present invention are exemplified hereinafter.

### Item 1

An aspect of the present invention is characterized by an optical component, comprising a substrate on which an optical element is mounted, a transparent sealing member bonded to an upper side of the substrate and configured to seal the optical element, and a bonded portion in which a plurality of metal films are laminated, and which is configured to bond the transparent sealing member and the substrate, wherein the bonded portion includes one or more stress relaxation layers constituted by one or more metal films having a Young's modulus of less than or equal to 150 GPa, the stress relaxation layers having a total thickness of greater than or equal to 1.2 μm, and a diffusion prevention layer disposed on each of both sides in a thickness direction of each of the stress relaxation layers, and configured to prevent diffusion of metal constituting the stress relaxation layer. In the above-described optical component, the diffusion prevention layer is capable of preventing deterioration of the stress relaxation layer, and a sufficient level of the stress relaxation layer can be maintained, and therefore, peeling off or damage to the transparent sealing member due to thermal stress can be effectively suppressed.

### Item 2

In the optical component according to item 1, a total thickness of the metal films constituting the stress relaxation layers may be greater than or equal to 2.1 μm. This optical component is capable of effectively suppressing the rate of occurrence of peeling off.

### Item 3

In the optical component according to item 1 or 2, the stress relaxation layers may be Cu (copper), Au (gold), Ag (silver), or Zn (zinc). This optical component is capable of preventing peeling off or damage from occurring to the transparent sealing member due to a thermal shock.

### Item 4

In the optical component according to any one of items 1 to 3, the diffusion prevention layer may be made of Ni (nickel), Pd (palladium), Pt (platinum), Zr (zirconium), Nb (niobium), W (tungsten), tungsten nitride, or tantalum nitride. This optical component is capable of preventing a situation in which the stress relaxation layer undergoes deterioration, and can prevent a situation in which the transparent sealing member peels off or becomes damaged.

### Item 5

In the optical component according to any one of items 1 to 4, the stress relaxation layers may have a coefficient of thermal expansion of less than or equal to 40 ppm/K. Such a stress relaxation layer is capable of suppressing a situation in which thermal stress is generated due to thermal deformation of the stress relaxation layer itself.

### Item 6

In the optical component according to any one of items 1 to 5, the total thickness of the stress relaxation layers may be less than or equal to 10 μm.

### Item 7

In the optical component according to any one of items 1 to 6, the total thickness of the stress relaxation layers may be greater than or equal to 0.28% of a thickness of the transparent sealing member located above the stress relaxation layers. In this optical component, since the stress relaxation layers are formed with a sufficient thickness, the thermal stress between the transparent sealing member and the substrate can be relaxed.

### Item 8

In the optical component according to any one of items 1 to 7, the transparent sealing member located above the stress relaxation layers may have a thickness of greater than or equal to 0.2 mm. When the thickness of the transparent sealing member increases, the transparent sealing member becomes less flexible and tends to become subjected to a higher thermal stress. This optical component, even in the case of a thick transparent sealing member, is capable of relaxing thermal stress, and can prevent peeling off or damage from occurring to the transparent sealing member.

### Item 9

In the optical component according to any one of items 1 to 8, the total thickness of the stress relaxation layers may be greater than or equal to 0.25% of a thickness of a portion of the substrate that is located below the stress relaxation layers. In this optical component, since the stress relaxation layers are formed with a sufficient thickness, the thermal stress between the transparent sealing member and the substrate can be relaxed.

### Item 10

In the optical component according to any one of items 1 to 9, the total thickness of the stress relaxation layers may be greater than or equal to 0.05% of a value obtained by adding a thickness of the transparent sealing member located above the stress relaxation layers and a thickness of the substrate located below the stress relaxation layers. In this optical component, since the stress relaxation layers are formed with a sufficient thickness, the thermal stress between the transparent sealing member and the substrate can be relaxed.

### Item 11

In the optical component according to any one of items 1 to 10, when a difference between a coefficient of thermal expansion of the transparent sealing member and a coefficient of thermal expansion of the substrate is defined as A (ppm/K), and an outer dimension of the bonded portion is defined as B (mm), a value of A×B may be greater than or equal to 5×10⁻⁶ mm/K.

### Item 12

In the optical component according to any one of items 1 to 11, an outer dimension of the bonded portion may be greater than or equal to 3 mm. This optical component, even with respect to a transparent sealing member having a size that is typical to that of a light emitting diode, is capable of preventing peeling off and damage thereof from occurring.

### Item 13

In the optical component according to any one of items 1 to 12, the transparent sealing member may be made of quartz glass or ultraviolet transmitting glass. This optical component is capable of preventing peeling off or damage from occurring to the transparent sealing member having low strength used for the ultraviolet light emitting diode, the ultraviolet light receiving element, or the like.

### Item 14

In the optical component according to any one of items 1 to 13, the transparent sealing member may have a coefficient of thermal expansion of less than or equal to 1 ppm/K.

### Item 15

In the optical component according to any one of items 1 to 14, the substrate may be made of any one of aluminum nitride, alumina, silicon, Kovar, or silicon nitride.

### Item 16

In the optical component according to any one of items 1 to 15, the substrate may have a coefficient of thermal expansion of greater than or equal to 2.5 ppm/K.

### Item 17

In the optical component according to any one of items 1 to 16, a thickness of the substrate located below the stress relaxation layers may be greater than or equal to 0.2 mm.

### Item 18

In the optical component according to any one of items 1 to 17, the bonded portion may include a first metallized layer formed on a bonding surface of the transparent sealing member that faces toward the substrate, the first metallized layer being formed of a plurality of metal films, a second metallized layer formed on the substrate, and formed of a plurality of metal films, and a low melting point alloy layer configured to bond the first metallized layer and the second metallized layer, wherein the stress relaxation layers and the diffusion prevention layer may be disposed in at least one of the first metallized layer or the second metallized layer. This optical component can achieve both adhesiveness due to the low melting point alloy layer, and a relaxation ability of the thermal stress.

### Item 19

In the optical component according to item 18, the stress relaxation layers and the diffusion prevention layer may be provided respectively in both the first metallized layer and the second metallized layer. This optical component is capable of relaxing the thermal stress between the transparent sealing member and the substrate.

### Item 20

In the optical component according to any one of items 1 to 19, the bonded portion may include a first adhesive layer configured to cause each of the stress relaxation layers to adhere to the transparent sealing member, and an outer peripheral edge of the first adhesive layer in a direction of a laminated surface of the first adhesive layer may project outward by greater than or equal to 1 μm from an outer peripheral edge of each of the stress relaxation layers in a direction of a laminated surface of the stress relaxation layer. This optical component is capable of relaxing thermal stress due to a difference in size between the first adhesive layer and the stress relaxation layer, and is capable of preventing peeling off from occurring due to cracks in the transparent sealing member in close proximity to an interface between the fragile transparent sealing member and the bonded portion.

### Item 21

Another aspect of the present invention is characterized by a transparent sealing member that is bonded onto a substrate on which an optical element is mounted, and that seals the optical element, the transparent sealing member comprising a lens configured to cover the optical element, a bonding surface provided on a peripheral edge part of the lens, and configured to be bonded onto the substrate, and a first metallized layer formed on the bonding surface, wherein the first metallized layer includes stress relaxation layers constituted by metal films having a Young's modulus of less than or equal to 150 GPa, the stress relaxation layers having a thickness of greater than or equal to 1.2 μm, and a diffusion prevention layer disposed on each of both sides in a thickness direction of each of the stress relaxation layers, and configured to prevent diffusion of metal constituting the stress relaxation layer. This transparent sealing member, while preventing deterioration of the diffusion prevention layer, is capable of relaxing thermal stress between the same and the substrate using the diffusion prevention layer.

### Item 22

In the transparent sealing member according to item 21, a total thickness of the metal films constituting the stress relaxation layers may be greater than or equal to 2.1 μm. This transparent sealing member is capable of effectively suppressing the rate of occurrence of peeling off.

### Item 23

In the transparent sealing member according to Item 21 or 22, there may further be provided a low melting point alloy layer formed on the first metallized layer. Since this transparent sealing member is provided in advance with the low melting point alloy layer, the process of bonding the same to the substrate can be simplified.

### Item 24

Another aspect of the present invention is characterized by a substrate on which an optical element is mounted, the substrate comprising an upper surface positioned on an outer peripheral part of a portion on which the optical element is mounted, wherein a transparent sealing member is bonded to the upper surface, and a second metallized layer formed on the upper surface, wherein the second metallized layer includes stress relaxation layers constituted by metal films having a Young's modulus of less than or equal to 150 GPa, the stress relaxation layers having a thickness of greater than or equal to 1.2 μm, and a diffusion prevention layer disposed on each of both sides in a thickness direction of each of the stress relaxation layers, and configured to prevent diffusion of metal constituting the stress relaxation layer. This substrate, while preventing deterioration of the diffusion prevention layer, can relax thermal stress between the same and the transparent sealing member using the diffusion prevention layer, and can therefore prevent peeling off or damage from occurring to the bonded transparent sealing member.

### Item 25

Another aspect of the present invention is characterized by a method for manufacturing an optical component in which an optical element mounted on a substrate is sealed with a transparent sealing member, the method for manufacturing the optical component comprising a step of bonding, with a low melting point alloy, a first metallized layer of the transparent sealing member and a second metallized layer of the substrate, wherein at least one of the first metallized layer or the second metallized layer includes one or more stress relaxation layers constituted by metal films having a Young's modulus of less than or equal to 150 GPa, the stress relaxation layers having a total thickness of greater than or equal to 1.2 μm, and a diffusion prevention layer disposed on each of both sides in a thickness direction of each of the stress relaxation layers, and configured to prevent diffusion of metal constituting the stress relaxation layer. This method for manufacturing the optical component is capable of preventing peeling off or damage from occurring to the transparent sealing member due to a thermal shock.

The aforementioned optical component, the transparent sealing member, the substrate, and the method for manufacturing the optical component are capable of preventing peeling off or damage from occurring to the transparent sealing member due to thermal stress.

### BRIEF DESCRIPTION OF DRAWINGS

FIG. 1A is a perspective view of an array member used in manufacturing a transparent sealing member according to a first embodiment, and FIG. 1B is a perspective view of a first metallized layer formed on a bonding surface of the array member;

FIG. 2A is a cross-sectional view of the first metallized layer shown in FIG. 1B, and FIG. 2B is an explanatory diagram of a singulation process;

FIG. 3A is an explanatory diagram of a process of attaching a low melting point alloy foil to the first metallized layer, and FIG. 3B is an explanatory diagram of the transparent sealing member including the first metallized layer and a low melting point alloy layer;

FIG. 4A is an explanatory diagram of a process of bonding the transparent sealing member shown in FIG. 3B to a substrate, and FIG. 4B is an explanatory diagram of an optical component according to the first embodiment;

FIG. 5A is a plan view of the optical component according to the first embodiment, and FIG. 5B is a cross-sectional view of the optical component shown in FIG. 5A;

FIG. 6A is an exploded perspective view of an optical component according to an Exemplary Modification 1 of the first embodiment, and FIG. 6B is a cross-sectional view of the optical component shown in FIG. 6A;

FIG. 7A is an exploded perspective view of an optical component according to an Exemplary Modification 2 of the first embodiment, and FIG. 7B is a cross-sectional view of the optical component shown in FIG. 7A;

FIG. 8A is a cross-sectional view of an optical component according to an Exemplary Modification 3 of the first embodiment, and FIG. 8B is a cross-sectional view of an optical component according to an Exemplary Modification 4 of the first embodiment;

FIG. 9A is a cross-sectional view of an optical component according to a second embodiment, and FIG. 9B is a cross-sectional view of an optical component according to a third embodiment;

FIG. 10 is a table showing a configuration of the transparent sealing member and the low melting point alloy layer of the optical component according to Exemplary Embodiments 1 to 5 and Comparative Examples 1 and 2;

FIG. 11 is a table showing a relationship between a configuration of the substrate of the optical component and a thickness of the optical component according to Exemplary Embodiments 1 to 5 and Comparative Examples 1 and 2, and an evaluation result of a thermal shock test;

FIG. 12 is a graph showing a relationship between a thickness of a stress relaxation layer and the rate of occurrence of peeling off according to Exemplary Embodiments 1 to 5 and 16 and Comparative Examples 1 and 2, with the thickness of the stress relaxation layer being shown on the horizontal axis, and the rate of occurrence of peeling off being shown on the vertical axis;

FIG. 13 is a table showing a configuration of the transparent sealing member and the low melting point alloy layer according to Exemplary Embodiments 6 to 10;

FIG. 14 is a table showing a relationship between a configuration of the substrate and a thickness of the optical component according to Exemplary Embodiments 6 to 10, and an evaluation result of a thermal shock test;

FIG. 15 is a table showing a configuration of the transparent sealing member and the low melting point alloy layer according to Exemplary Embodiments 11 to 15;

FIG. 16 is a table showing a relationship between a configuration of the substrate and a thickness of the optical component according to Exemplary Embodiments 11 to 15, and an evaluation result of a thermal shock test;

FIG. 17 is a table showing a configuration of the transparent sealing member and the low melting point alloy layer according to Exemplary Embodiments 16 to 19;

FIG. 18 is a table showing a relationship between a configuration of the substrate and a thickness of the optical component according to Exemplary Embodiments 16 to 19, and an evaluation result of a thermal shock test; and

FIG. 19 is a cross-sectional view of the first metallized layer of the optical component according to an Exemplary Embodiment 19.

### DETAILED DESCRIPTION OF THE INVENTION

### First Embodiment

Hereinafter, a description will be given concerning an optical component 10 according to a first embodiment, together with a manufacturing method therefor. A description will be given of the optical component 10 of the present embodiment, taking an example in which an ultraviolet light emitting LED serving as an optical element 12 is sealed with a transparent sealing member 14. However, the optical component 10 is not necessarily limited to this feature, and can also be suitably applied to cases in which a light emitting element such as various LEDs or the like, or alternatively, a light receiving element such as a photodiode or the like is sealed with the transparent sealing member 14. The terms upper, upward, lower, and downward that are used in the present specification indicate positional relationships within the interior of the member, and do not necessarily limit the installation direction of the optical component 10.

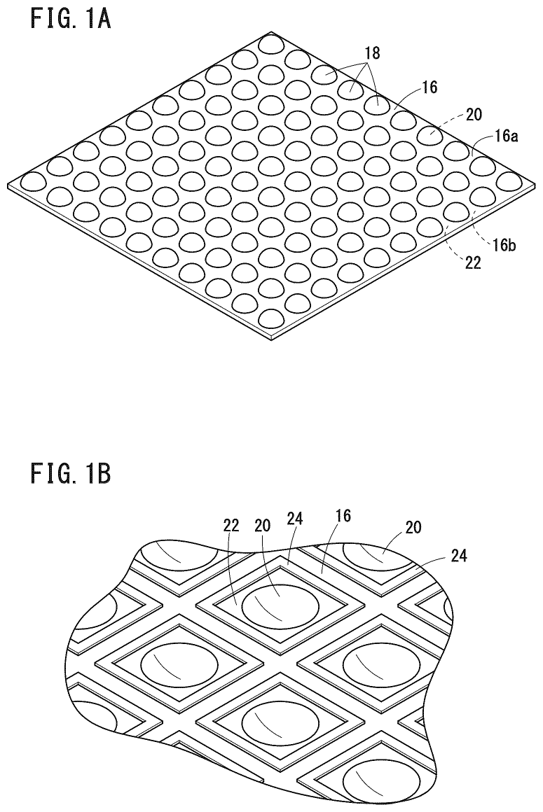

First, while referring to FIG. 1A to FIG. 3B, a description will be given concerning the manufacturing of the transparent sealing member 14 of the optical component 10. In the manufacturing process of the transparent sealing member 14, first, an array member 16 as shown in FIG. 1A is prepared. The array member 16 is a plate-shaped member in which a plurality of lenses 18 are arranged in a vertical direction and a horizontal direction. Moreover, in the present specification, the lenses 18 serve as portions that transmit light. The lenses 18 are not necessarily limited to being of a hemispherical shape, but may also include flat plate-shaped windows.

Since the array member 16 of the present embodiment includes the plurality of lenses 18, it may also be referred to as a lens array. The array member 16 includes a front surface 16a from which the lenses 18 project out, and a rear surface 16b. According to the present embodiment, the array member 16 includes, on the rear surface 16b, concave cavities 20 and flat bonding surfaces 22. The array member 16 is constituted, for example, by quartz glass. Details of the manufacturing method of the array member 16 are described, for example, in WO 2019/012743 A1.

Next, polishing is carried out on the bonding surface 22 of the array member 16. Due to such polishing, an unevenness of the bonding surface 22 is eliminated, and the bonding surface 22 is made flat. When the bonding surface 22 is made flat, the amount of a low melting point alloy layer 36 (solder) required for bonding is made smaller, and the use amount of the low melting point alloy layer 36 that contains Au can be reduced. Moreover, it should be noted that the polishing of the bonding surface 22 may be carried out as necessary depending on the unevenness of the bonding surface 22, and may be omitted.

Next, as shown in FIG. 1B, a metallizing process of the bonding surface 22 is carried out. The metallizing process is a process of forming, on the bonding surface 22, a metal pattern (a first metallized layer 24) superior in the wettability with the low melting point alloy layer 36 and the adhesiveness with the transparent sealing member 14. The first metallized layer 24, as illustrated, is formed in a rectangular ring shape surrounding the periphery of the cavity 20 of each of the lenses 18.

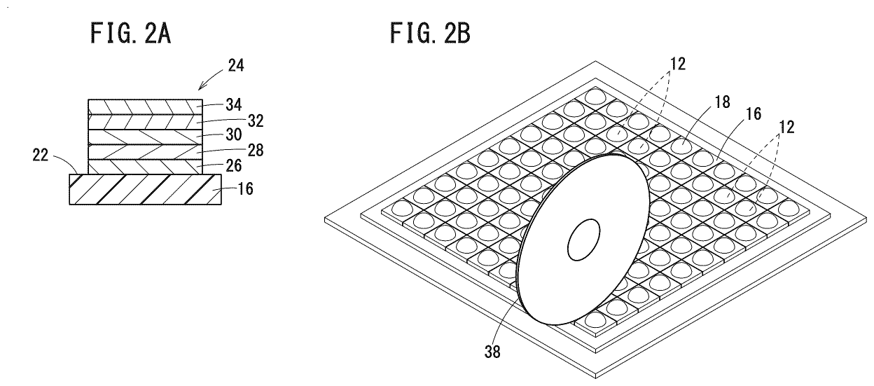

As shown in FIG. 2A, the process of forming the first metallized layer 24 includes laminating a first adhesive layer 26, a first diffusion prevention layer 28, a first stress relaxation layer 30, a second diffusion prevention layer 32, and a second adhesive layer 34 on the bonding surface 22 in this order. The first adhesive layer 26 is formed by depositing a metal film such as Ti (titanium) or the like on the bonding surface 22, for example, by a sputtering method. The first adhesive layer 26 is formed with a thickness, for example, of 0.01 to 0.5 μm. The material of the first adhesive layer 26 is selected from metal materials having superior adhesiveness to quartz glass or ultraviolet transmitting glass. As the material of the first adhesive layer 26, there may be cited Ti (titanium) or Cr (chromium), or nitrides thereof, and alloys of Cr (chromium) and Ni (nickel).

The first diffusion prevention layer 28 is formed by depositing a film of Pd (palladium) on the first adhesive layer 26 by a sputtering method. The first diffusion prevention layer 28 is formed with a thickness, for example, of 0.01 to 0.5 μm. The first diffusion prevention layer 28 serves to prevent the metal that constitutes the first stress relaxation layer 30 from diffusing in the thickness direction. The first diffusion prevention layer 28 is preferably formed using a material that has superior adhesiveness to the first adhesive layer 26 and the first stress relaxation layer 30. The first diffusion prevention layer 28 may be made of an Ni (nickel) film or a Pt (platinum) film.

The first stress relaxation layer 30 is constituted, for example, by a Cu (copper) film. Such a first stress relaxation layer 30 is formed, for example, by forming a seed layer by a sputtering method, and depositing a Cu (copper) film on the seed layer by a plating method. Although not particularly limited thereto, the first stress relaxation layer 30 can be formed to a thickness, for example, of greater than or equal to 1.2 μm and less than or equal to 10 μm. The thickness of the first stress relaxation layer 30 is more preferably set to be greater than or equal to 2.1 μm and less than or equal to 10 μm. A thickness C of the first stress relaxation layer 30 will be described in detail later. Moreover, it should be noted that the material of the first stress relaxation layer 30 is not necessarily limited to being Cu, and any metal material having a Young's modulus of less than or equal to 150 GPa can be used. Further, the first stress relaxation layer 30 is preferably made of a material having a small thermal expansion, and is preferably made using a material with a coefficient of thermal expansion of less than or equal to 40 ppm/K. Instead of Cu, as other materials that can be used for the first stress relaxation layer 30, there may be cited Au, Ag (silver), and Zn (zinc).

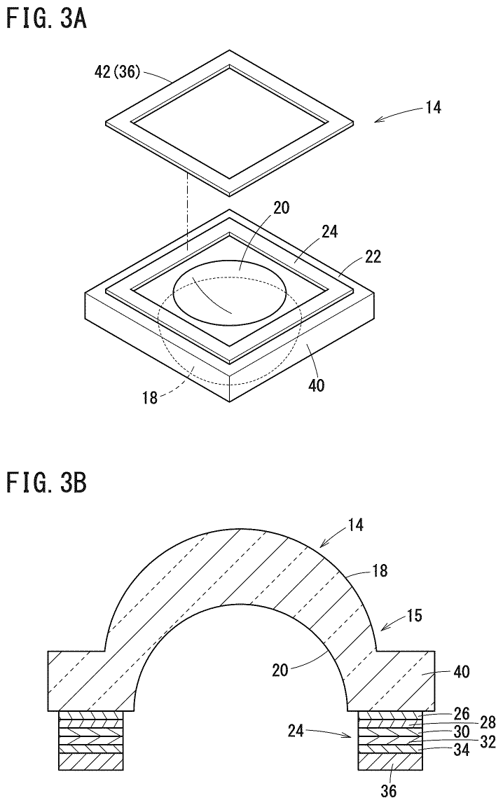

The second diffusion prevention layer 32 is formed by depositing an Ni film (or a Pd film or a Pt film) on the first stress relaxation layer 30, for example, by a plating method. The second diffusion prevention layer 32 has a thickness of 0.1 to 5 μm. The second diffusion prevention layer 32 prevents interdiffusion from occurring between the second adhesive layer 34 or the low melting point alloy layer 36 (see FIG. 3A) and the first stress relaxation layer 30, thereby prevents the deterioration of the first stress relaxation layer 30. In the second diffusion prevention layer 32, Pd or Pt may be used instead of Ni. Further, the second diffusion prevention layer 32 may be made using any one of Zr (zirconium), Nb (niobium), W (tungsten), tungsten nitride, or tantalum nitride. These materials have low interdiffusion properties with the metal constituting the first stress relaxation layer 30 and the metal constituting the second adhesive layer 34, and have superior adhesiveness to such metal, and can therefore be suitably used as the second diffusion prevention layer 32.

The second adhesive layer 34 is formed by depositing an Au film on the second diffusion prevention layer 32, for example, by a plating method. The second adhesive layer 34 is formed with a thickness, for example, of 0.1 to 2 μm. The second adhesive layer 34 is formed of a material having superior wettability and adhesiveness with an alloy containing Sn (tin) having a low melting point such as solder or the like. The second adhesive layer 34, by being mixed and integrated together with the low melting point alloy layer 36 without a boundary formed therebetween, exhibits high adhesiveness to the low melting point alloy layer 36.

Each of the above-described layers from the first adhesive layer 26 to the second adhesive layer 34 is formed over the entire surface of the rear surface 16b (refer to FIG. 1A) of the array member 16. Thereafter, a mask (not shown) having a predetermined shape is formed on the second adhesive layer 34. The mask may be formed by application, exposure, and development of a photoresist material, or may be formed by applying a mask material by means of a printing method. Thereafter, portions of the layers from the first adhesive layer 26 to the second adhesive layer 34 that are exposed from the mask are removed by etching, whereby the first metallized layer 24 formed of the ring-shaped pattern shown in FIG. 1B is completed.

Next, as shown in FIG. 2B, a singulation process is carried out. In the singulation process, the array member 16 is cut, by a dicing saw 38, into respective individual transparent sealing members 14. In the cut transparent sealing member 14, as shown in FIG. 3A, a rectangular base portion 40 is formed around the periphery of the lens 18. The base portion 40 is formed in a flat plate shape. The cut transparent sealing member 14 is accommodated in a non-illustrated tray in a state with the bonding surface 22 facing upward.

Next, as shown in FIG. 3A, a low melting point alloy foil 42 is placed on the first metallized layer 24. The low melting point alloy foil 42 is shaped in advance in a manner so as to overlap with at least a portion of the first metallized layer 24. The low melting point alloy foil 42, for example, is made of an AuSn (gold-tin) alloy. Apart from an AuSn alloy, various alloys containing Sn and having a melting point of less than or equal to 450° C. can be used for the low melting point alloy foil 42.

Thereafter, as shown in FIG. 3B, for example, by means of dot welding as disclosed in JP 7182596 B2, the low melting point alloy foil 42 is partially bonded onto the first metallized layer 24. The low melting point alloy layer 36 is formed by the bonded low melting point alloy foil 42. By the aforementioned process, the transparent sealing member 14 is completed.

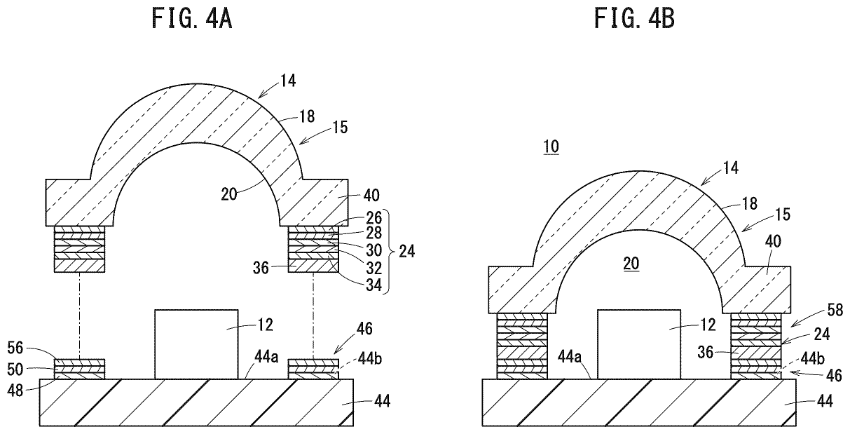

Next, as shown in FIG. 4A and FIG. 4B, a process of bonding the transparent sealing member 14 to a substrate 44 is carried out. As shown in FIG. 4A, the optical element 12 is mounted on an upper surface 44a of the substrate 44. The optical element 12, for example, is an ultraviolet light emitting diode that emits ultraviolet light. The substrate 44 is made, for example, of aluminum nitride, alumina, silicon, Kovar, or silicon nitride. The substrate 44 has a coefficient of thermal expansion, for example, of greater than or equal to 2.5 ppm/K. The substrate 44 typically has a different coefficient of thermal expansion from that of the transparent sealing member 14. The substrate 44 includes a second metallized layer 46 on a bonded region 44b of the upper surface 44a thereof.

The second metallized layer 46 of the present embodiment is constituted by laminating a third adhesive layer 48, a third diffusion prevention layer 50, and a fourth adhesive layer 56 on the upper surface 44a of the substrate 44 in this order. The third adhesive layer 48 is made of a metal film having superior adhesiveness to the substrate 44. The third adhesive layer 48 is made, for example, of a Cr film (or a Ti film) having a thickness of 0.01 to 0.5 μm. Such a Cr film is formed, for example, by a sputtering method.

The third diffusion prevention layer 50 is a metal film that serves to prevent the diffusion of the fourth adhesive layer 56. The third diffusion prevention layer 50 is made, for example, of an Ni film (or a Pd film or a Pt film) having a thickness of 0.01 to 0.5 μm. Such an Ni film is formed by a sputtering method.

The fourth adhesive layer 56 is a metal film having superior wettability and adhesiveness with the low melting point alloy layer 36. The fourth adhesive layer 56 is made, for example, of an Au film having a thickness of 0.1 to 2 μm.

The above-described second metallized layer 46 is formed by sequentially depositing the third adhesive layer 48, the third diffusion prevention layer 50, and the fourth adhesive layer 56, and thereafter, patterning the layers by etching in which a mask of a predetermined shape is used.

Next, the transparent sealing member 14 is disposed on the substrate 44. The transparent sealing member 14 is placed on the substrate 44 in a manner so that the first metallized layer 24 is positioned above the second metallized layer 46 of the substrate 44. Thereafter, the substrate 44 and the transparent sealing member 14 are heated to a temperature of 200 to 400° C.

Due to such heating, as shown in FIG. 4B, the low melting point alloy layer 36 is melted, and the second adhesive layer 34 and the fourth adhesive layer 56 are integrated together. By means of this process, a bonded portion 58 is formed in which the first metallized layer 24 and the second metallized layer 46 are bonded together via the low melting point alloy layer 36 without any gaps existing therebetween. By the aforementioned process, the optical component 10 is completed.

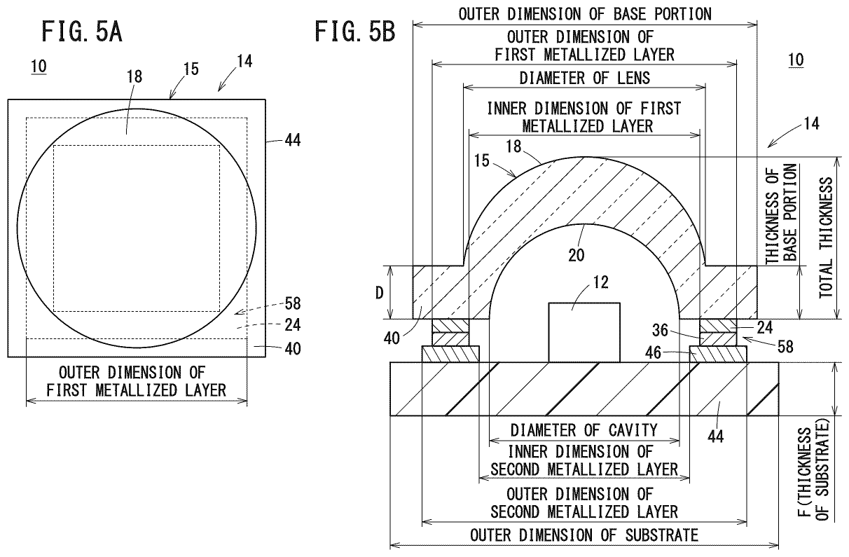

As shown in FIG. 5A, in the optical component 10 of the present embodiment, the substrate 44 is covered with the transparent sealing member 14 as viewed in plan. The transparent sealing member 14 includes a transparent portion 15, and the first metallized layer 24. The transparent sealing member 14 may be made of ultraviolet transmitting glass (borosilicate glass), instead of quartz glass (having a coefficient of thermal expansion of less than or equal to 1 ppm/K). The transparent portion 15 includes the hemispherical lens 18, and the rectangular plate-shaped base portion 40 (also referred to as a flange) formed around the periphery of the lens 18. As shown in FIG. 5B, the hemispherical cavity 20 is formed in the interior of the lens 18. The cavity 20 forms a space in which the optical element 12 is accommodated.

As shown in FIG. 5A, the first metallized layer 24 is formed on the bonding surface 22 (refer to FIG. 2A). The first metallized layer 24 extends along the peripheral edge of the lens 18, and is formed in a rectangular ring shape, the corners of which are positioned below the base portion 40. In the present embodiment, the thickness of the base portion 40 is defined as a thickness D of the transparent sealing member 14 on the bonded portion 58. A portion of the first metallized layer 24 may overlap with the lens 18. An outer dimension of the first metallized layer 24 is defined as an outer dimension B of the bonded portion 58. The bonded portion 58, for example, has the outer dimension B that is greater than or equal to 3 mm.

As shown in FIG. 5B, the transparent sealing member 14 is bonded, via the bonded portion 58, onto the upper surface 44a of the substrate 44. In the optical component 10, due to a change in temperature that occurs when the substrate 44 and the transparent sealing member 14 are bonded to each other, thermal stress is generated between both members. The magnitude of the thermal stress increases in accordance with the difference in the amount of displacement due to thermal expansion between the transparent sealing member 14 and the substrate 44. If the thermal stress is large, cracks or peeling off occurs in the relatively fragile transparent sealing member 14, and the sealing of the optical element 12 is broken.

The amount of displacement of the transparent sealing member 14 and the substrate 44 per one degree change in temperature is associated with the product (A×B) of an absolute value A [ppm/K] of the difference between the coefficient of thermal expansion of the transparent sealing member 14 and the coefficient of thermal expansion of the substrate 44, and the outer dimension B [mm] of the bonded portion 58 (the first metallized layer 24). If the value of A×B exceeds 5×10⁻⁶ [mm/K], the transparent sealing member 14 is likely to become cracked or to peel off.

In order to prevent damage from occurring to the transparent sealing member 14, the optical component 10 includes the first stress relaxation layer 30 in the first metallized layer 24. By being deformed in response to the displacement of the transparent sealing member 14 and the substrate 44, the first stress relaxation layer 30 relaxes the thermal stress of the bonded portion 58. As the first stress relaxation layer 30 becomes thicker, it is possible to relieve a greater amount of displacement caused by the thermal expansion.

In the optical component 10, in the case that the transparent sealing member 14 is thin, a portion of the thermal stress can be relaxed by the elastic deformation of the transparent sealing member 14, and therefore, the thickness C of the first stress relaxation layer 30 can be made thinner. On the other hand, if the thickness D of the transparent sealing member 14 increases, it becomes difficult for the transparent sealing member 14 to become deformed, and unless the thickness C of the first stress relaxation layer 30 is increased, cracking and peeling off due to the thermal stress become likely to occur. If the thickness D of the transparent sealing member 14 is greater than or equal to 0.2 mm, the transparent sealing member 14 becomes likely to suffer from peeling off or cracking. In this case, when the thickness C of the first stress relaxation layer 30 is greater than or equal to 0.28% of the thickness D of the transparent sealing member 14, the occurrence of cracking and peeling off of the transparent sealing member 14 is suppressed.

In the optical component 10, in the same manner as with the transparent sealing member 14, the substrate 44 becomes less susceptible to elastic deformation as the thickness thereof increases, and therefore, it becomes necessary for the first stress relaxation layer 30 to be thicker. In the case that the thickness of a portion of the substrate 44 that is located below the bonded portion 58 is defined as a thickness F of the substrate 44, then if the thickness C of the first stress relaxation layer 30 is greater than or equal to 0.25% of the thickness F of the substrate 44, it is preferable because cracking and peeling off of the transparent sealing member 14 can be suppressed.

Furthermore, it is preferable that the thickness C of the first stress relaxation layer 30 is set to be greater than or equal to 0.05% of a thickness E of the optical component 10, which is the sum (D+F) of the thickness D of the transparent sealing member 14 and the thickness F of the substrate 44.

### (Exemplary Modification 1 of First Embodiment)

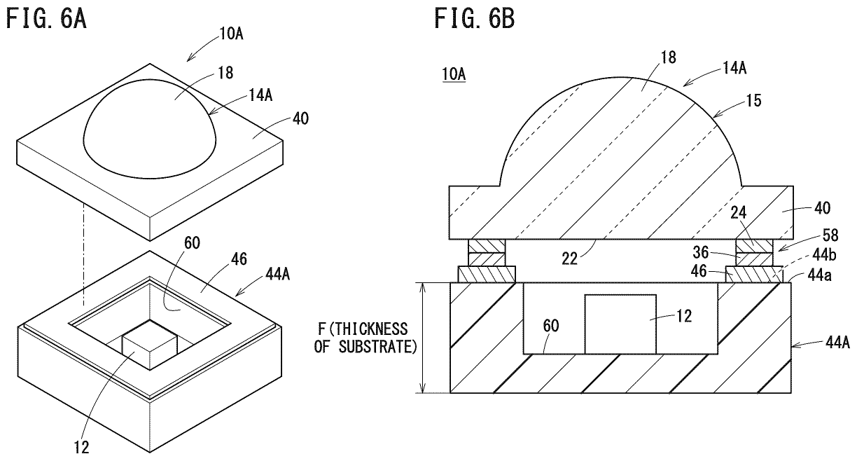

An optical component 10A shown in FIG. 6A and FIG. 6B differs from the optical component 10 shown in FIG. 4B, in terms of a transparent sealing member 14A and a substrate 44A. In the configuration of the optical component 10A, the same components as those of the optical component 10 shown in FIG. 4B are denoted by the same reference numerals, and detailed description of such features will be omitted.

The transparent sealing member 14A includes the hemispherical lens 18, and the rectangular base portion 40 provided around the periphery of the lens 18. As shown in FIG. 6B, the lens 18 is not formed with the cavity 20 in the interior thereof, and is filled with quartz glass. The entire lower side of the transparent sealing member 14A is constituted by the flat bonding surface 22.

The substrate 44A includes a box-shaped cavity 60 on the upper surface 44a. The cavity 60 is formed in a rectangular shape as viewed in plan. The cavity 60 serves to accommodate the optical element 12. The optical element 12 is bonded onto the substrate 44A inside the cavity 60. The second metallized layer 46 is formed on the upper surface 44a of the substrate 44A. The second metallized layer 46 is formed in a rectangular ring shape in a manner so as to surround the cavity 60. The second metallized layer 46 is configured in the same manner as the second metallized layer 46 that was described with reference to FIG. 4A.

In the present exemplary modification, as shown in FIG. 6B, the thickness of the substrate 44A is defined as the thickness F of the substrate 44A below the bonded portion 58. In the present exemplary modification, the first metallized layer 24 includes the first stress relaxation layer 30, the thickness of which is preferably greater than or equal to 0.25% of the thickness of the substrate 44A.

The present exemplary modification also makes it possible to prevent the occurrence of cracking and peeling off of the transparent sealing member 14A.

### (Exemplary Modification 2 of First Embodiment)

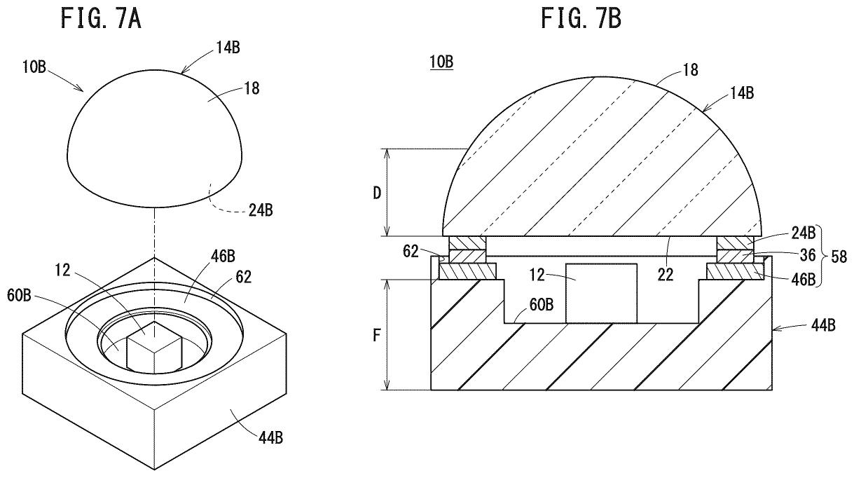

As shown in FIGS. 7A and 7B, in an optical component 10B according to the present exemplary modification, a transparent sealing member 14B is constituted by the hemispherical lens 18. The transparent sealing member 14B does not include the plate-shaped base portion 40 around the periphery of the lens 18. The lens 18 does not include the cavity 20 in the interior thereof, and the interior thereof is filled with quartz glass. A bottom part of the transparent sealing member 14B is formed as the flat bonding surface 22. The transparent sealing member 14B includes, on the bonding surface 22, a first metallized layer 24B having a circular ring shape. The configuration of the respective layers of the first metallized layer 24B is the same as that of the first metallized layer 24 that was described with reference to FIG. 2A. The low melting point alloy layer 36 is formed on the first metallized layer 24B.

A substrate 44B includes a cavity 60B, a lens accommodating concave portion 62, and a second metallized layer 46B. The cavity 60B is formed in a cylindrical shape. The cavity 60B serves to accommodate the optical element 12. The diameter of the cavity 60B is smaller than the inner diameter of the first metallized layer 24B of the transparent sealing member 14B. The lens accommodating concave portion 62 is a concave portion that is formed on the outer peripheral part of the cavity 60B, and is formed to be shallower than the cavity 60B. The lens accommodating concave portion 62 is formed to be slightly larger than the outer diameter of the transparent sealing member 14B, and serves to accommodate the transparent sealing member 14B. The second metallized layer 46B is formed on the bottom surface of the lens accommodating concave portion 62. The configuration of the respective layers of the second metallized layer 46B is the same as that of the second metallized layer 46 that was described with reference to FIG. 4A.

The transparent sealing member 14B is disposed in a manner so that the first metallized layer 24B faces toward the second metallized layer 46B of the lens accommodating concave portion 62. The first metallized layer 24B and the second metallized layer 46B are bonded together by the low melting point alloy layer 36 and thereby form the bonded portion 58.

In the present exemplary modification, the thickness of the transparent sealing member 14B above the bonded portion 58 is defined as the thickness D of the transparent sealing member 14B at a location above the center of the first metallized layer 24B in the widthwise direction. In the present exemplary modification, the thickness C of the first stress relaxation layer 30 is preferably set to be greater than or equal to 0.28% of the thickness D of the transparent sealing member 14B.

The present exemplary modification also makes it possible to prevent the occurrence of cracking and peeling off of the transparent sealing member 14B.

### (Exemplary Modification 3 of First Embodiment)

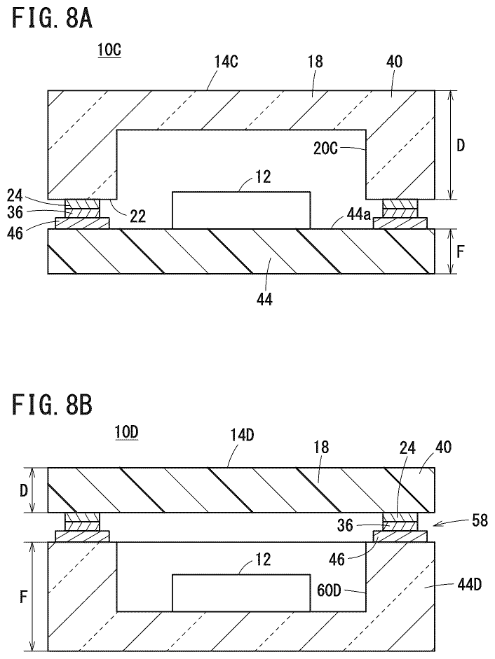

As shown in FIG. 8A, an optical component 10C of the present exemplary modification differs from the optical component 10 shown in FIG. 4B, in that it includes a transparent sealing member 14C of a flat plate shape. In the configuration of the optical component 10C, the same components as those of the optical component 10 shown in FIG. 4B are denoted by the same reference numerals, and detailed description of such features will be omitted.

In the transparent sealing member 14C, the lens 18 is formed in a flat plate shape. The lens 18 is integrated together with the base portion 40. The transparent sealing member 14C is formed in a rectangular shape having the same dimension as that of the substrate 44 as viewed in plan. The transparent sealing member 14C includes a cavity 20C, and the first metallized layer 24. The cavity 20C is formed in a rectangular shape as viewed in plan. The cavity 20C serves to accommodate the optical element 12 that is mounted on the substrate 44. The first metallized layer 24 is formed in a rectangular ring shape surrounding an outer side of the cavity 20C. The first metallized layer 24 is formed on the bonding surface 22 of the transparent sealing member 14C, and is bonded, via the low melting point alloy layer 36, onto the second metallized layer 46 of the substrate 44.

The configuration of the respective layers of the first metallized layer 24 and the respective layers of the second metallized layer 46 is the same as that of the first metallized layer 24 and the second metallized layer 46 of the first embodiment. The present exemplary modification also makes it possible to prevent the occurrence of cracking and peeling off of the transparent sealing member 14C.

### (Exemplary Modification 4 of First Embodiment)

As shown in FIG. 8B, an optical component 10D of the present exemplary modification differs from the optical component 10 shown in FIG. 4B, in that it includes a transparent sealing member 14D of a flat plate shape. In the configuration of the optical component 10D, the same components as those of the optical component 10 shown in FIG. 4B are denoted by the same reference numerals, and detailed description of such features will be omitted.

The transparent sealing member 14D is formed in a flat plate shape and is formed in a rectangular shape having the same dimension as that of a substrate 44D as viewed in plan. The cavity 20 is not formed in the transparent sealing member 14D, and a cavity 60D is formed in the substrate 44D. The cavity 60D of the substrate 44D is formed in a rectangular shape as viewed in plan, and the substrate 44D is formed in a box shape. The optical element 12 is mounted in the cavity 60D of the substrate 44D.

The transparent sealing member 14D is made of ultraviolet transmitting glass of a flat plate shape, or quartz glass of a flat plate shape. The transparent sealing member 14D includes the first metallized layer 24 that is formed in a rectangular ring shape in a manner so as to surround the cavity 60D of the substrate 44D. The first metallized layer 24 is bonded, via the low melting point alloy layer 36, onto the second metallized layer 46 of the substrate 44D.

The present exemplary modification also makes it possible to prevent the occurrence of cracking and peeling off of the transparent sealing member 14D.

### Second Embodiment

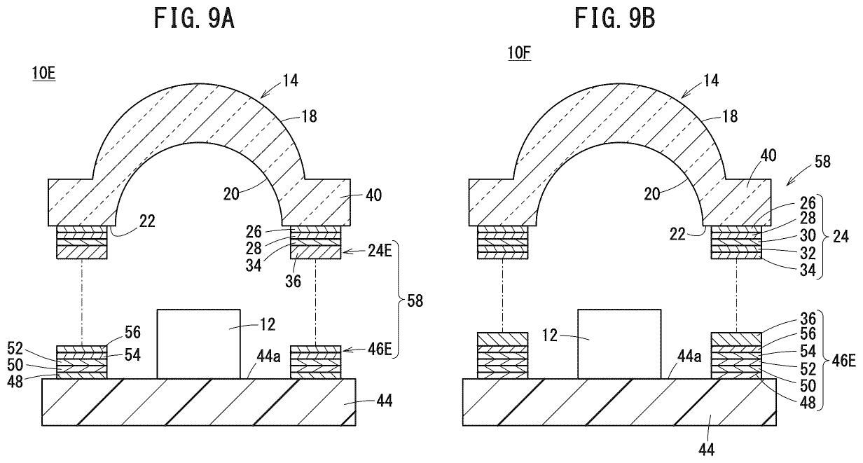

As shown in FIG. 9A, an optical component 10E of the present embodiment includes a second stress relaxation layer 52 in a second metallized layer 46E of the substrate 44, and the first stress relaxation layer 30 is not provided in a first metallized layer 24E of the transparent sealing member 14.

In the transparent sealing member 14 of the present embodiment, the first metallized layer 24E is formed on the bonding surface 22. The first metallized layer 24E has a structure in which the first adhesive layer 26, the first diffusion prevention layer 28, and the second adhesive layer 34 are laminated on the bonding surface 22 in this order. The first adhesive layer 26 is made of a Ti film or a Cr film having a thickness of 0.01 to 0.5 μm. The first diffusion prevention layer 28 is made of a Pd film, a Pt film, or an Ni film having a thickness of 0.01 to 0.5 μm. The second adhesive layer 34 is made of an Au film having a thickness of 0.1 to 2 μm. The low melting point alloy layer 36 is made of an AuSn alloy film having a thickness of 20 μm.

The substrate 44 includes the optical element 12 that is mounted on the upper surface 44a. The ring-shaped second metallized layer 46E, which surrounds the optical element 12, is formed on the upper surface 44a of the substrate 44. The second metallized layer 46E has a structure in which the third adhesive layer 48, the third diffusion prevention layer 50, the second stress relaxation layer 52, a fourth diffusion prevention layer 54, and the fourth adhesive layer 56 are formed on the upper surface 44a of the substrate 44 in this order. The third adhesive layer 48 is made of a Ti film (or a Cr film) having a thickness of 0.01 to 0.5 μm. The third diffusion prevention layer 50 is made of a Pd film (or an Ni film or a Pt film) having a thickness of 0.01 to 0.5 μm. The third adhesive layer 48 and the third diffusion prevention layer 50 are formed, for example, by a sputtering method. The second stress relaxation layer 52 is made of a metal (for example, Cu) film having a Young's modulus of less than or equal to 150 GPa. The second stress relaxation layer 52 is formed to a thickness of greater than or equal to 1.2 μm, and more preferably, to a thickness of greater than or equal to 2.1 μm. The thickness of the second stress relaxation layer 52 may be the same as the thickness of the first stress relaxation layer 30 that was described in the first embodiment.

The fourth diffusion prevention layer 54 is made, for example, of an Ni film (or a Pd film or a Pt film) having a thickness of 0.1 to 5 μm. The fourth adhesive layer 56 is made of an Au film having a thickness of 0.1 to 2 μm. The second stress relaxation layer 52, the fourth diffusion prevention layer 54, and the fourth adhesive layer 56 are formed by a plating method.

In the optical component 10E, the transparent sealing member 14 is bonded onto the substrate 44 via the first metallized layer 24E, the second metallized layer 46E, and the low melting point alloy layer 36. In the optical component 10E, the second stress relaxation layer 52, which is provided in the second metallized layer 46E, is capable of relaxing the thermal stress of the bonded portion 58, and is capable of preventing the occurrence of cracking and peeling off of the transparent sealing member 14.

### Third Embodiment

As shown in FIG. 9B, an optical component 10F of the present embodiment includes the first metallized layer 24 that is formed on the bonding surface 22 of the transparent sealing member 14. Further, the optical component 10F also includes the second metallized layer 46E on the substrate 44. The first stress relaxation layer 30 is formed in the first metallized layer 24 (refer to FIG. 2A). The second stress relaxation layer 52 is formed in the second metallized layer 46E (refer to FIG. 2A). Accordingly, the optical component 10F includes, in the bonded portion 58, the first stress relaxation layer 30 and the second stress relaxation layer 52. The other configurations of the first metallized layer 24 are the same as those of the first metallized layer 24 of the first embodiment that was described with reference to FIG. 9A. Further, the other configurations of the second metallized layer 46E are the same as those of the second metallized layer 46E that was described with reference to FIG. 9A.

Although not particularly limited to this feature, in the present embodiment, the low melting point alloy layer 36 is formed on the second metallized layer 46E. The configuration of the low melting point alloy layer 36 is the same as that of the low melting point alloy layer 36 that was described with reference to FIG. 3A and FIG. 3B.

In the optical component 10F of the present embodiment, the sum of the thicknesses of the first stress relaxation layer 30 and the second stress relaxation layer 52 may be greater than or equal to 1.2 μm, and more preferably, may be greater than or equal to 2.1 μm. In the optical component 10F of the present embodiment, since the first stress relaxation layer 30 and the second stress relaxation layer 52 are capable of relaxing the thermal stress of the bonded portion 58, it is possible to prevent cracking or peeling off of the transparent sealing member 14.

### Embodiments and Comparative Examples

The optical components 10 and 10A to 10F of the above-described embodiments were manufactured and evaluated, and the results of such an evaluation will be described hereinafter. The dimensions of respective parts of the manufactured optical components 10 and 10A to 10F were measured using a measuring microscope and a SEM (scanning electron microscope). As necessary, cross-sectional processing was carried out on the optical component 10. The materials and the compositions were measured with an EDS that was attached to the SEM (scanning electron microscope). The coefficient of thermal expansion and the Young's modulus are values in a bulk state. The rate of occurrence of peeling off of the transparent sealing member 14 was evaluated by carrying out a thermal shock test. Such a thermal shock test was carried out by mounting the optical component 10 on an aluminum heat dissipation substrate, subjecting the optical component to a thermal cycle of −40° C. to +85° C., and observing the presence or absence of peeling off using the naked eye or an optical microscope.

### Exemplary Embodiments 1 to 5 and 16 and Comparative Examples 1 and 2

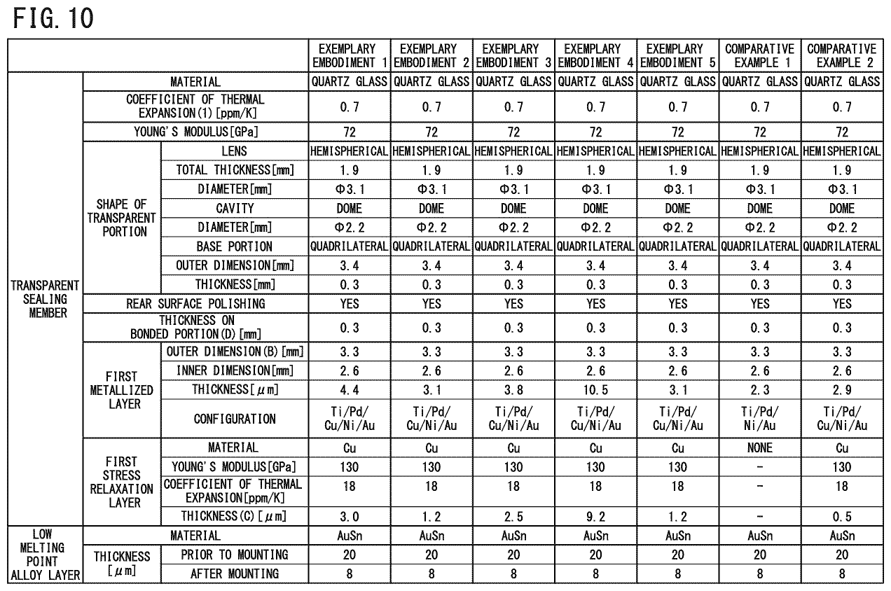

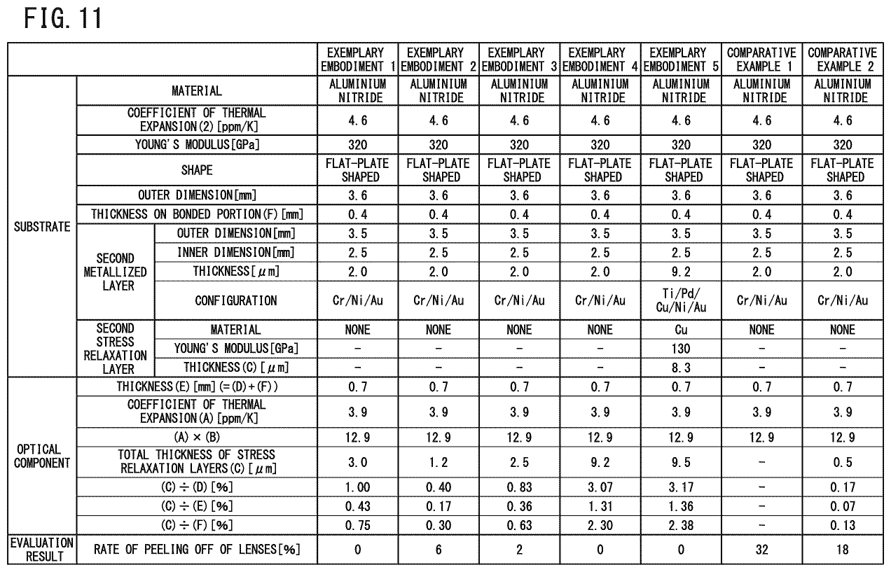

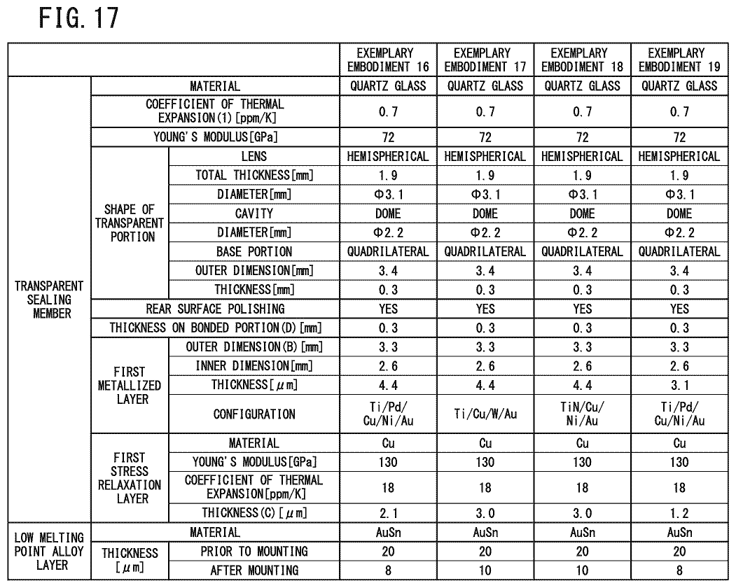

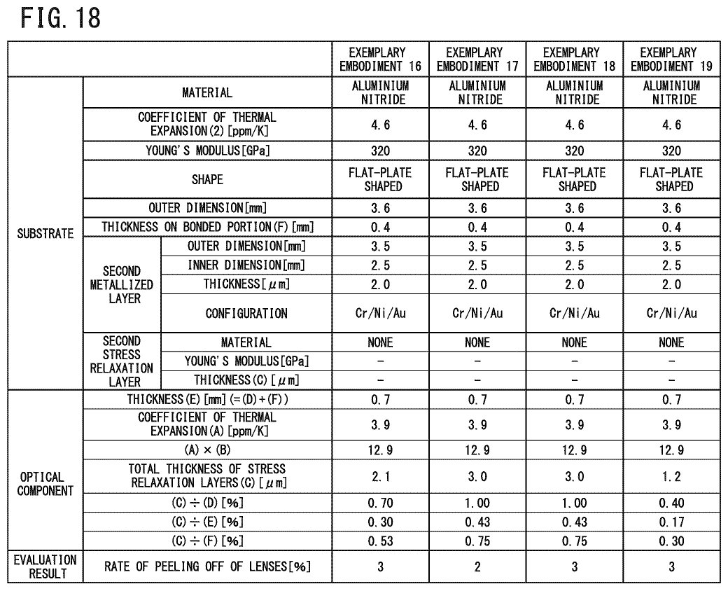

In the Exemplary Embodiments 1 to 5 and 16 and the Comparative Examples 1 and 2, the optical components 10 and 10E having the same dimensions were manufactured and evaluated. The dimensions and configurations of the respective parts are shown in FIG. 10 and FIG. 11. Moreover, the dimensions and configurations of the respective parts of the optical component 10 of Exemplary Embodiment 16, as well as the evaluation result, are shown in FIG. 17 and FIG. 18. Comparative Example 1 is a case in which the first stress relaxation layer 30 is not formed, and thus the thickness of the first stress relaxation layer 30 is 0 μm. In Comparative Example 2 and Exemplary Embodiments 1 to 4 and 16, the thickness of the first stress relaxation layer 30 varies within the range of 0.5 μm to 9.2 μm. Exemplary Embodiment 5 is the optical component 10E shown in FIG. 9A, and apart from the bonded portion 58, is the same as Exemplary Embodiments 1 to 4. In the Exemplary Embodiment 5, the second stress relaxation layer 52, which is made up from a Cu film having a thickness of 8.3 μm, is provided together with the first stress relaxation layer 30 which has a thickness of 1.2 μm.

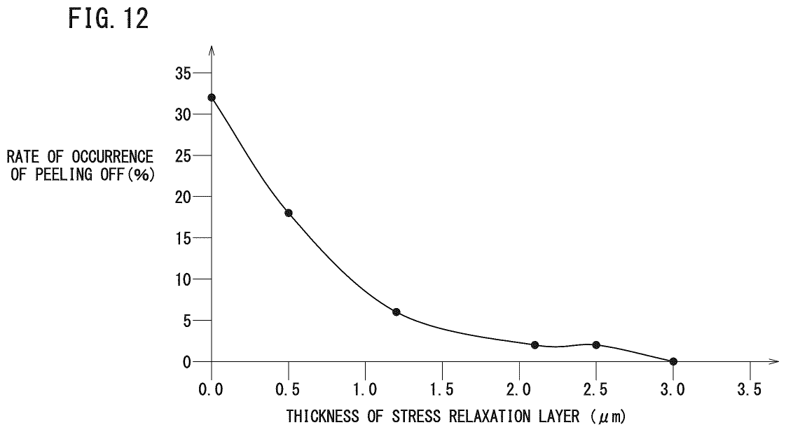

As shown in FIG. 12, in the Comparative Example 1 in which the first stress relaxation layer 30 and the second stress relaxation layer 52 were not provided, the rate of occurrence of peeling off of the transparent sealing member 14 became 32%. The rate of occurrence of peeling off of the transparent sealing member 14 exhibited a tendency of decreasing as the thickness of the first stress relaxation layer 30 or the second stress relaxation layer 52 (hereinafter collectively referred to as the stress relaxation layer) increased. In particular, it can be seen that when the thickness of the stress relaxation layer is in a range of less than 1.2 μm, the rate of occurrence of peeling off of the transparent sealing member 14 sharply increases. Accordingly, it could be confirmed that if the thickness of the stress relaxation layer is in a range of being greater than or equal to 1.2 μm, the rate of occurrence of peeling off of the transparent sealing member 14 could be suppressed to be less than or equal to 6%. Furthermore, as shown in Exemplary Embodiment 16, Exemplary Embodiments 3 to 5, and FIG. 12, when the thickness of the stress relaxation layer is in the range of being greater than or equal to 2.1 μm, the rate of occurrence of peeling off can be suppressed to be less than or equal to 3%.

### Exemplary Embodiments 6, 8, 11, and 13

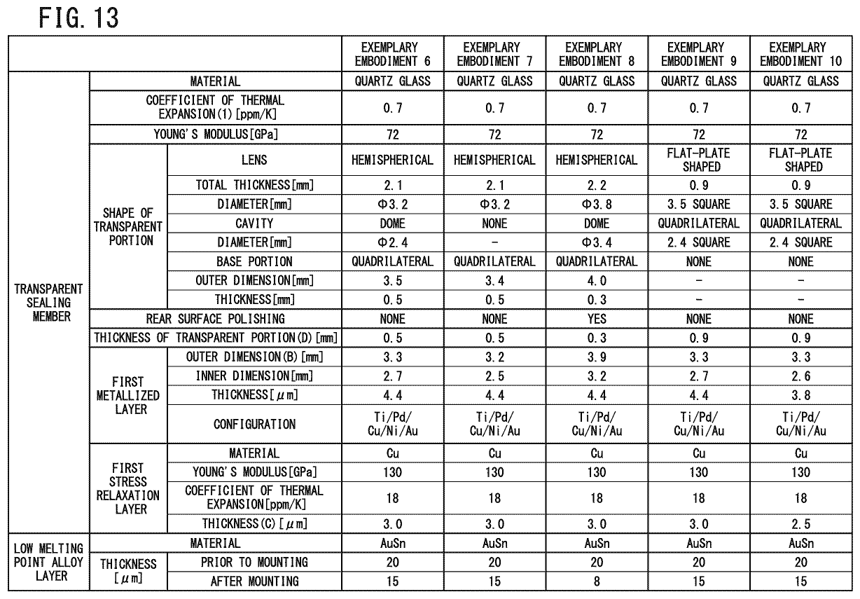

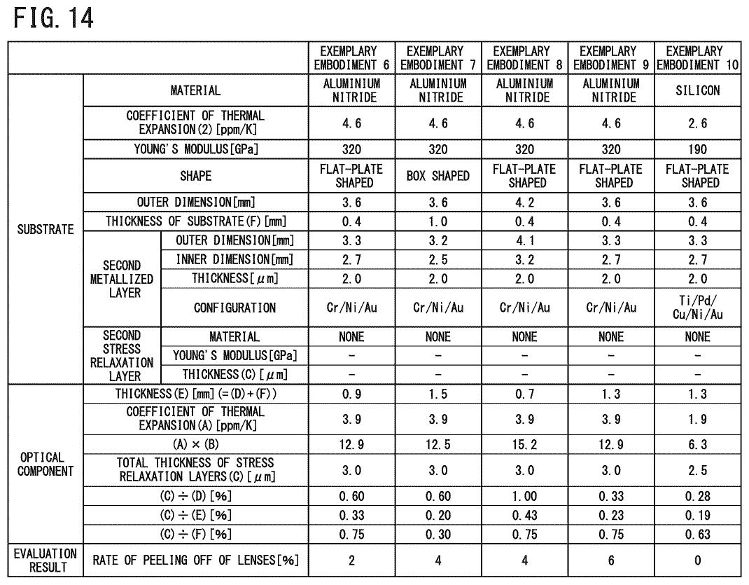

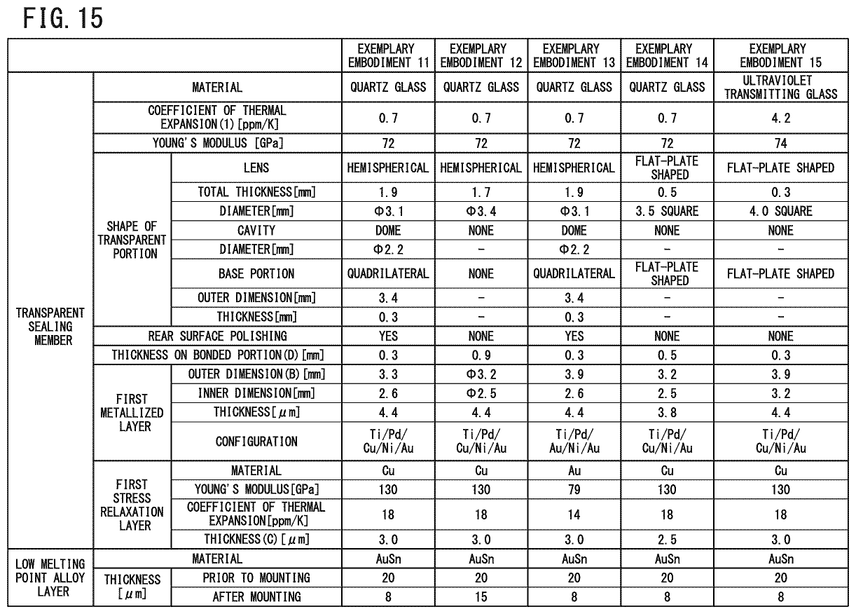

Exemplary Embodiment 6, 8, 11, and 13 are the results of evaluating the optical component 10 shown in FIG. 5A and FIG. 5B. In the Exemplary Embodiments 6, 8, 11, and 13, in the same manner as in Exemplary Embodiment 1, the thickness of the first stress relaxation layer 30 is 3.0 μm (see FIG. 13 and FIG. 15). Exemplary Embodiment 6, as shown in FIG. 13, differs from Exemplary Embodiment 1, in that the thickness D of the base portion 40 of the transparent sealing member 14 is increased to 0.5 mm. As shown in FIG. 14, in Exemplary Embodiment 6, the rate of occurrence of peeling off was within 2%, and was an improvement over the rate of occurrence of peeling off in Comparative Examples 1 and 2.

Exemplary Embodiment 8, as shown in FIG. 13, differs from Exemplary Embodiment 1, in that the dimension of the transparent sealing member 14 is increased. In Exemplary Embodiment 8, the outer dimension B of the first metallized layer 24 (the bonded portion 58) is 3.9 mm. When the dimension of the transparent sealing member 14 increases, the dimensional difference thereof from the thermally expanded substrate 44 also increases. However, as shown in FIG. 14, the rate of occurrence of peeling off of the transparent sealing member 14 in Exemplary Embodiment 8 increased only slightly to 48. The rate of occurrence of peeling off of Exemplary Embodiment 8 was an improvement over the rate of occurrence of peeling off in Comparative Examples 1 and 2.

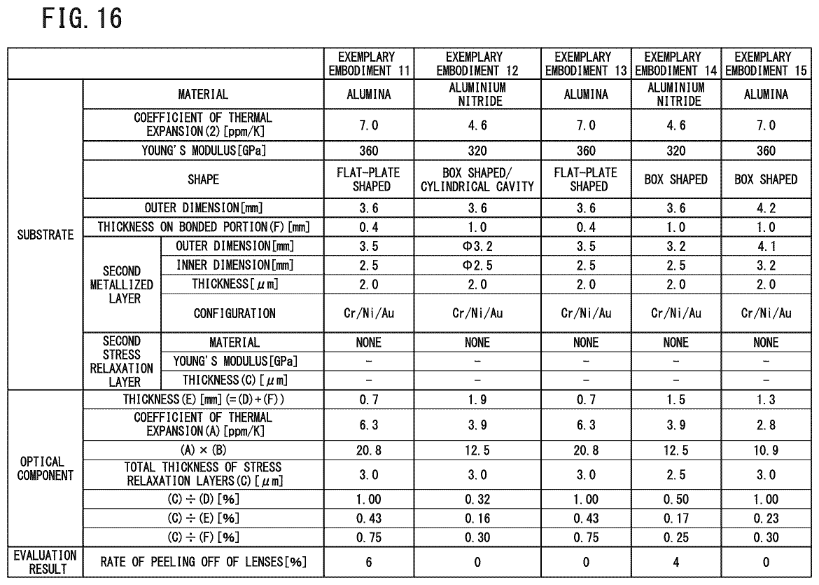

Exemplary Embodiment 11, as shown in FIG. 16, differs from Exemplary Embodiment 1, in that alumina is used for the substrate 44. The coefficient of thermal expansion of alumina is 7 ppm/K, which is larger than the coefficient of thermal expansion of aluminum nitride of Example 1, which is 4.6 ppm/K. Therefore, the bonded portion 58 is more significantly affected by stress due to thermal expansion. In Exemplary Embodiment 11, the rate of occurrence of peeling off was within 6%, and was an improvement over the rate of occurrence of peeling off in Comparative Examples 1 and 2.

In Exemplary Embodiment 13, in the same manner as in Exemplary Embodiment 11, alumina was used for the substrate 44. Exemplary Embodiment 13, as shown in FIG. 15, differs from Exemplary Embodiment 11, in that Au, which has a smaller Young's modulus than Cu, is used as the material for the first stress relaxation layer 30. As shown in FIG. 16, in Exemplary Embodiment 13, the rate of occurrence of peeling off was 0%, and was an improvement over the rate of occurrence of peeling off in Exemplary Embodiment 11.

### Exemplary Embodiment 7

Exemplary Embodiment 7 shown in FIG. 13 indicates a test and the evaluation results in relation to the optical component 10A shown in FIG. 6A and FIG. 6B. In Exemplary Embodiment 7, as shown in FIG. 6B, since the transparent sealing member 14A does not include the cavity 20, the transparent sealing member 14A is less likely to undergo deformation. Accordingly, in Exemplary Embodiment 7, it is difficult to obtain the effect of relaxing the thermal stress caused due to the deformation of the transparent sealing member 14A. As shown in FIG. 14, in Exemplary Embodiment 7, the rate of occurrence of peeling off was 4% due to the effect of the first stress relaxation layer 30, and was an improvement over the rate of occurrence of peeling off in Comparative Examples 1 and 2.

### Exemplary Embodiments 9 and 10

Exemplary Embodiments 9 and 10 shown in FIG. 13 indicate a test and the evaluation results in relation to the optical component 10C shown in FIG. 8A. As shown in FIG. 14, in Exemplary Embodiment 9, aluminum nitride having a coefficient of thermal expansion of 4.6 ppm/K was used for the substrate 44, and in Exemplary Embodiment 10, silicon having a coefficient of thermal expansion of 2.6 ppm/K was used for the substrate 44. In Exemplary Embodiment 9, the rate of occurrence of peeling off became 6%. On the other hand, in Exemplary Embodiment 10, in which the difference in the coefficient of thermal expansion between the substrate 44 and the transparent sealing member 14 was small, the rate of occurrence of peeling off became 0%. In the aforementioned Exemplary Embodiments 9 and 10 as well, the rate of occurrence of peeling off was improved as compared with Comparative Examples 1 and 2.

### Exemplary Embodiment 12

Exemplary Embodiment 12 shown in FIG. 15 indicates a test and the evaluation results in relation to the optical component 10B shown in FIG. 7A and FIG. 7B. The optical component 10B does not include the base portion 40. As shown in FIG. 16, in Exemplary Embodiment 12, the rate of occurrence of peeling off was 0%, and the rate of occurrence of peeling off was capable of being more suppressed than in Comparative Examples 1 and 2.

### Exemplary Embodiments 14 and 15

Exemplary Embodiments 14 and 15 shown in FIG. 15 indicate a test and the evaluation results in relation to the optical component 10D shown in FIG. 8B. In Exemplary Embodiment 14, quartz glass was used for the transparent sealing member 14, and aluminum nitride was used for the substrate 44. In Exemplary Embodiment 15, ultraviolet transmitting glass (borosilicate glass) was used for the transparent sealing member 14, and alumina was used for the substrate 44. In Exemplary Embodiment 14, the rate of occurrence of peeling off was 4%, and in Exemplary Embodiment 15, the rate of occurrence of peeling off was 0%. Accordingly, in Exemplary Embodiments 14 and 15, the rate of occurrence of peeling off was capable of being more suppressed than in Comparative Examples 1 and 2.

### Exemplary Embodiment 17

As shown in FIG. 17 and FIG. 18, the optical component 10 according to Exemplary Embodiment 17 differs from the optical component 10 of Exemplary Embodiment 1, in terms of the configuration of the first metallized layer 24. The first metallized layer 24 of Exemplary Embodiment 17 includes, in this order from the transparent sealing member 14 side, a Ti film (the first adhesive layer 26), a Cu film (the first stress relaxation layer 30), a W film (the second diffusion prevention layer 32), and an Au film (the second adhesive layer 34). More specifically, the second diffusion prevention layer 32 of Exemplary Embodiment 17, instead of the Ni film of the second diffusion prevention layer 32 of Exemplary Embodiment 1, is formed of a W film. The other configurations of the optical component 10 of Exemplary Embodiment 17 are the same as the corresponding configurations of the optical component 10 of Exemplary Embodiment 1.

As shown in FIG. 18, in Exemplary Embodiment 17, the rate of occurrence of peeling off was 2%, and the rate of occurrence of peeling off was more suppressed than in Comparative Examples 1 and 2. The evaluation result of Exemplary Embodiment 17 indicated that, even in the case that the second diffusion prevention layer 32 was a W film, the same effects as those of Exemplary Embodiment 1 could be obtained.

### Exemplary Embodiment 18

The optical component 10 according to Exemplary Embodiment 18 shown in FIG. 17 and FIG. 18 differs from the optical component 10 of Exemplary Embodiment 1, in terms of the configuration of the first metallized layer 24. The optical component 10 of Exemplary Embodiment 18 differs in that, instead of the Ti film of Exemplary Embodiment 1, the first adhesive layer 26 of the first metallized layer 24 is a TiN film. The other configurations of the optical component 10 of Exemplary Embodiment 18 are the same as the corresponding configurations of the optical component 10 of Exemplary Embodiment 1.

As shown in FIG. 18, in Exemplary Embodiment 18, the rate of occurrence of peeling off was 3%, and the rate of occurrence of peeling off was more suppressed than in Comparative Examples 1 and 2. The evaluation result of Exemplary Embodiment 18 indicated that, even in the case that the first adhesive layer 26 was changed from a Ti film to a TiN film, the same effects as those of Exemplary Embodiment 1 could be obtained.

### Exemplary Embodiment 19

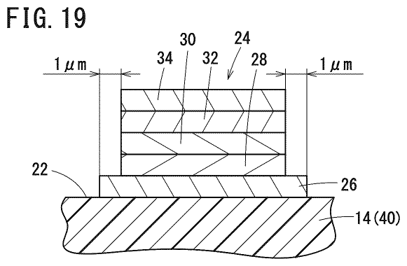

As shown in FIG. 19, in the optical component 10 according to Exemplary Embodiment 19, the area of the first adhesive layer 26 that is formed on the base portion 40 of the transparent sealing member 14 is formed to be larger than the area of each of the first diffusion prevention layer 28, the first stress relaxation layer 30, the second diffusion prevention layer 32, and the second adhesive layer 34. The first adhesive layer 26 is formed in a manner so that the position of its outer peripheral edge in the direction of the laminated surface thereof projects outward by 1 μm from the positions of the outer peripheral edges of the first diffusion prevention layer 28, the first stress relaxation layer 30, and the second diffusion prevention layer 32 in the direction of the laminated surfaces thereof. Further, as shown in FIG. 17 and FIG. 18, the optical component 10 of Exemplary Embodiment 19 includes the first stress relaxation layer 30 having a thickness of 1.2 μm, which is approximately the same as that of the first stress relaxation layer 30 of Exemplary Embodiment 2. The other configurations of the optical component 10 of Exemplary Embodiment 19 are the same as those of the optical component 10 of Exemplary Embodiment 1.

As shown in FIG. 19, in Exemplary Embodiment 19, even though the thickness of the first stress relaxation layer 30 was 1.2 μm, which was approximately the same as that of Exemplary Embodiment 2, the rate of occurrence of peeling off was 3%, and was an improvement over the rate of occurrence of peeling off of 6% in Exemplary Embodiment 2. The evaluation result of Example 19 indicated that the rate of occurrence of peeling off was suppressed by causing the outer peripheral edge of the first adhesive layer 26 in the direction of the laminated surface thereof to project outward by greater than or equal to 1 μm from the outer peripheral edge of the first stress relaxation layer 30 in the direction of the laminated surface thereof. This result is considered to be due to the fact that peeling off of the transparent sealing member 14 is suppressed by the thermal stress being dispersed by the difference in size between the first adhesive layer 26 and the first stress relaxation layer 30.

1. An optical component, comprising:
a substrate on which an optical element is mounted;
a transparent sealing member disposed above the substrate and configured to seal the optical element; and
a bonded portion in which a plurality of metal films are laminated, and which is configured to bond the transparent sealing member and the substrate,
wherein the bonded portion includes:
one or more stress relaxation layers constituted by one or more metal films having a Young's modulus of less than or equal to 150 GPa, the one or more stress relaxation layers having a total thickness of greater than or equal to 1.2 μm; and
a diffusion prevention layer disposed on each of both sides in a thickness direction of each of the one or more stress relaxation layers, and configured to prevent diffusion of metal constituting the stress relaxation layer.

2. The optical component according to claim 1, wherein a total thickness of the one or more metal films constituting the one or more stress relaxation layers is greater than or equal to 2.1 μm.

3. The optical component according to claim 1, wherein the one or more stress relaxation layers are made of any one of Cu (copper), Au (gold), Ag (silver), or Zn (zinc).

4. The optical component according to claim 1, wherein the diffusion prevention layer is made of any one of Ni (nickel), Pd (palladium), Pt (platinum), Zr (zirconium), Nb (niobium), W (tungsten), tungsten nitride, or tantalum nitride.

5. The optical component according to claim 1, wherein the one or more stress relaxation layers have a coefficient of thermal expansion of less than or equal to 40 ppm/K.

6. The optical component according to claim 1, wherein the total thickness of the one or more stress relaxation layers is less than or equal to 10 μm.

7. The optical component according to claim 1, wherein the total thickness of the one or more stress relaxation layers is greater than or equal to 0.28% of a thickness of the transparent sealing member located above the one or more stress relaxation layers.

8. The optical component according to claim 1, wherein the transparent sealing member located above the one or more stress relaxation layers has a thickness of greater than or equal to 0.2 mm.

9. The optical component according to claim 1, wherein the total thickness of the one or more stress relaxation layers is greater than or equal to 0.25% of a thickness of a portion of the substrate that is located below the one or more stress relaxation layers.

10. The optical component according to claim 1, wherein the total thickness of the one or more stress relaxation layers is greater than or equal to 0.05% of a value obtained by adding a thickness of the transparent sealing member located above the one or more stress relaxation layers and a thickness of the substrate located below the one or more stress relaxation layers.

11. The optical component according to claim 1, wherein, when a difference between a coefficient of thermal expansion of the transparent sealing member and a coefficient of thermal expansion of the substrate is defined as A ppm/K, and an outer dimension of the bonded portion is defined as B mm, a value of A×B is greater than or equal to 5×10⁻⁶ mm/K.

12. The optical component according to claim 1, wherein an outer dimension of the bonded portion is greater than or equal to 3 mm.

13. The optical component according to claim 1, wherein the transparent sealing member is made of quartz glass or ultraviolet transmitting glass.

14. The optical component according to claim 1, wherein the transparent sealing member has a coefficient of thermal expansion of less than or equal to 1 ppm/K.

15. The optical component according to claim 1, wherein the substrate is made of any one of aluminum nitride, alumina, silicon, Kovar, or silicon nitride.

16. The optical component according to claim 1, wherein the substrate has a coefficient of thermal expansion of greater than or equal to 2.5 ppm/K.

17. The optical component according to claim 1, wherein a thickness of the substrate located below the one or more stress relaxation layers is greater than or equal to 0.2 mm.

18. The optical component according to claim 1, wherein the bonded portion includes:
a first metallized layer formed on a bonding surface of the transparent sealing member that faces toward the substrate, the first metallized layer being formed of a plurality of metal films;
a second metallized layer formed on the substrate, and formed of a plurality of metal films; and
a low melting point alloy layer configured to bond the first metallized layer and the second metallized layer,
wherein the one or more stress relaxation layers and the diffusion prevention layer are disposed in at least one of the first metallized layer or the second metallized layer.

19. The optical component according to claim 18, wherein the one or more stress relaxation layers and the diffusion prevention layer are provided respectively in both the first metallized layer and the second metallized layer.

20. The optical component according to claim 1, wherein the bonded portion includes a first adhesive layer configured to cause each of the one or more stress relaxation layers to adhere to the transparent sealing member, and
an outer peripheral edge of the first adhesive layer in a direction of a laminated surface of the first adhesive layer projects outward by greater than or equal to 1 μm from an outer peripheral edge of each of the one or more stress relaxation layers in a direction of a laminated surface of the stress relaxation layer.

21. A transparent sealing member that is bonded onto a substrate on which an optical element is mounted, and that seals the optical element, the transparent sealing member comprising:
a lens configured to cover the optical element;
a bonding surface provided on a peripheral edge part of the lens, and configured to be bonded onto the substrate; and
a first metallized layer formed on the bonding surface, wherein the first metallized layer includes:
one or more stress relaxation layers constituted by one or more metal films having a Young's modulus of less than or equal to 150 GPa, the one or more stress relaxation layers having a thickness of greater than or equal to 1.2 μm; and
a diffusion prevention layer disposed on each of both sides in a thickness direction of each of the one or more stress relaxation layers, and configured to prevent diffusion of metal constituting the stress relaxation layer.

22. The transparent sealing member according to claim 21, wherein a total thickness of the one or more metal films constituting the one or more stress relaxation layers is greater than or equal to 2.1 μm.

23. The transparent sealing member according to claim 21, further comprising a low melting point alloy layer formed on the first metallized layer.

24. A substrate on which an optical element is mounted, the substrate comprising:
an upper surface positioned on an outer peripheral part of a portion on which the optical element is mounted, wherein a transparent sealing member is bonded to the upper surface; and
a second metallized layer formed on the upper surface,
wherein the second metallized layer includes:
one or more stress relaxation layers constituted by one or more metal films having a Young's modulus of less than or equal to 150 GPa, the one or more stress relaxation layers having a thickness of greater than or equal to 1.2 μm; and
a diffusion prevention layer disposed on each of both sides in a thickness direction of each of the one or more stress relaxation layers, and configured to prevent diffusion of metal constituting the stress relaxation layer.

25. A method for manufacturing an optical component in which an optical element mounted on a substrate is sealed with a transparent sealing member, the method for manufacturing the optical component comprising:
a step of bonding, with a low melting point alloy, a first metallized layer of the transparent sealing member and a second metallized layer of the substrate,
wherein at least one of the first metallized layer or the second metallized layer includes: one or more stress relaxation layers constituted by one or more metal films having a Young's modulus of less than or equal to 150 GPa, the one or more stress relaxation layers having a total thickness of greater than or equal to 1.2 μm; and a diffusion prevention layer disposed on each of both sides in a thickness direction of each of the one or more stress relaxation layers, and configured to prevent diffusion of metal constituting the stress relaxation layer.
